(19) United States
(12) Patent Application Publication
(10) Pub. No.: US 2008/0126468 A1
(43) Pub. Date: May 29, 2008

(54) Decoding apparatus for vector booth multiplication

(75) Inventors: Yuan-Ting Fu, Chia-Yi (TW); Ching-Wei Yeh, Chia-Yi (TW); Jinn-Shyan Wang, Chia-Yi (TW)

Correspondence Address: BIRCH STEWART KOLASCH & BIRCH, PO BOX 747, FALLS CHURCH, VA, 22040-0747, US

(73) Assignee: Ching-Wei YEH

(21) Appl. No.: 11/500,874

(22) Filed: Aug. 9, 2006

(51) Int. Cl. G06F 7/52; H03K 19/02

(52) U.S. Cl. 708/607; 326/105

(57) ABSTRACT

A decoding apparatus for Booth multiplication includes a NAND gate, a first and a second OR gate coupled to the NAND gate, a first and a second exclusive NOR gate coupled respectively to the OR gates, a clean-to-zero device coupled to the first and the second OR gates, and a send-one device coupled to the NAND gate. The clean-to-zero device permits the decoding apparatus to deliver a zero. The send-one device permits the decoding apparatus to deliver a one. The decoding apparatus supports both signed and unsigned Booth multiplications.

### BACKGROUND

1. Field of Invention

The present invention relates to a decoder. More particularly, the present invention relates to a decoder for supporting vector Booth multiplication.

2. Description of Related Art

Multipliers are critical computational components for many DSP and multimedia computations, such as filterings, transforms, convolutions, etc. Moreover, it has been recognized that sub-word parallelism, i.e., vector processing (or so-called single-instruction-multiple-data, SIMD) capability, greatly improves the throughput of multimedia processors, digital signal processors, and general-purpose processors with multimedia extensions. Hence, many recent works have been focusing on devising efficient architectures to support vector multiplication.

The major difference between a vector multiplier and a scalar multiplier is that the former needs to operate on different vector modes. Specifically, the difference lies only on partial product generation rather than partial product reduction. The most difficult problem in this respect is to have a decoder that supports both signed and unsigned decoding operations on different vector modes without compromising functional correctness and performance of multiplication.

The resolution for the aforesaid problem in accordance with prior art utilizes peripheral multiplexing technique. The peripheral multiplexing technique maintains the fundamental architecture of the scalar multiplier and categorizes the multipliers and the multiplicands according to different vector modes, signed and unsigned computations beforehand. It then uses multiplexers to select one set of correct multipliers and the multiplicands and load the selected set of multipliers and the multiplicands to the scalar multipliers for computations.

Although the peripheral multiplexing techniques can complete the vector computations, it needs much additional hardware to perform multiplexing. Consequently, the hardware cost is increased and the multiplication performance is adversely affected.

Therefore, there is a need to provide a Booth multiplication decoder that efficiently achieves the objectives of supporting both signed and unsigned vector decoding operations, and which completely replaces the peripheral multiplexing technique.

### SUMMARY

An object of the present invention is to provide a decoding apparatus that has support for both signed and unsigned Booth decoding multiplications on different vector modes.

A decoding apparatus in accordance with the present includes a NAND gate, a first OR gate, a second OR gate, a first exclusive NOR gate, a second exclusive NOR gate, a clear-to-zero device and a send-one device.

The first and the second OR gates are coupled to the NAND gate. The outputs of the first and the second exclusive NOR gates are respectively coupled to the first and the second OR gates. The output of the clear-to-zero device is coupled to the first and the second OR gates through which the clear-to-zero device permits the decoding apparatus to deliver a zero. The output of the send-one device is coupled to the NAND gate through which the send-one device permits the decoding apparatus to deliver a one.

The present invention reduces hardware costs caused by using the peripheral multiplexing technique in performing vector multiplication.

The present invention has another advantage that critical paths are properly maintained by careful balancing, which results in the logic depth of the decoding apparatus in accordance with the present invention being exactly the same as that of an original Booth decoder.

Furthermore, compared to the peripheral multiplexing method where additional multiplexing delay is inevitable, the decoding apparatus in accordance with the present invention has another advantage of minimizing the delay overhead. Moreover, the decoding apparatus does not have to hold the multiplexing data. Compared to the peripheral multiplexing method where many extra hardware components are required to support various vector modes under all Booth encodings (±1, ±2, 0), tremendous area saving is achieved.

### BRIEF DESCRIPTION OF THE DRAWINGS

These and other features, aspects, and advantages of the present invention will become better understood with regard to the following description, appended claims, and accompanying drawings where:

FIG. 1 is a schematic circuit diagram of an original Booth decoder;

FIG. 2 is schematic diagram illustrating a simplification of the partial product array showing different zones of the Booth decoder;

FIG. 3 is a schematic circuit diagram of a Booth decoding apparatus in accordance with the present invention with adding a clear-to-zero device to the original Booth decoder in FIG. 1;

FIG. 4 is a schematic circuit diagram of the Booth decoding apparatus in FIG. 3 with the further addition of a send-one device; and

FIG. 5 is schematic diagram illustrating an alternative simplification of the partial product array in FIG. 1 to show different zones of the Booth decoders.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

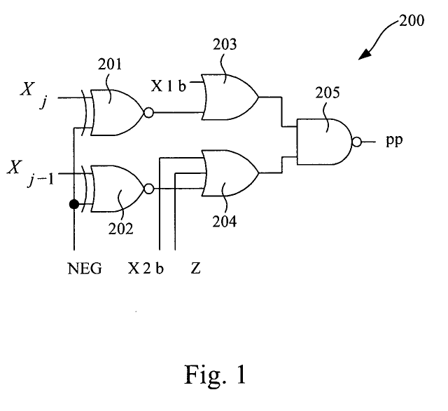

With reference to FIG. 1, FIG. 1 illustrates a schematic circuit diagram of an original Booth decoder for the present invention. A scalar Booth decoder 200 for the present invention is a scalar component that supports vector multiplication. The decoder 200 comprises a first exclusive NOR gate 201, a second exclusive NOR gate 202, a first OR gate 203, a second OR gate 204 and an NAND gate 205.

The first exclusive NOR gate 201 and the second exclusive NOR gate 202 respectively have outputs, and the outputs are respectively coupled to the first OR gate 203 and the second OR gate 204. The first OR gate 203 and the second OR gate 204 respectively have outputs, and the outputs are coupled to the NAND gate 205. The letter xⱼ represents the bits of the multiplicand.

With regard to Booth decoding, since the Most Significant Bit, MSB of each partial product in the two's complement is negatively weighted, either sign extension or sign encoding should be used. Here, this embodiment employs the sign encoding to minimize the hardware overhead.

In sign encoding under signed computations, the negatively weighted MSB is replaced by {p, n, n} for the first partial product and {1, p} for the remaining partial products, where n is the MSB of the multiplicand and p=˜n.

To support unsigned computations as well, an extra bit is appended in front of the original MSB. For signed computations, the bit is set to the value of the original MSB. Thus, a one-bit sign extension is achieved and the original two's complement value of the multiplicand is preserved. For unsigned computation, on the other hand, the value of the bit should go with the Booth encoding result. If Booth encoding is negative, a subtraction is implied. Hence, the bit is set to ‘1’ in order to employ two's complement for subtraction. Otherwise, a ‘0’ is placed instead. Once the extra bit is properly taken care of, the conventional sign encoding can then be exerted.

The realization of the above sign encoding starts to get complicated when unsigned computation is considered along with various vector modes. For illustration, the partial product array is partitioned into different zones of Booth decoders.

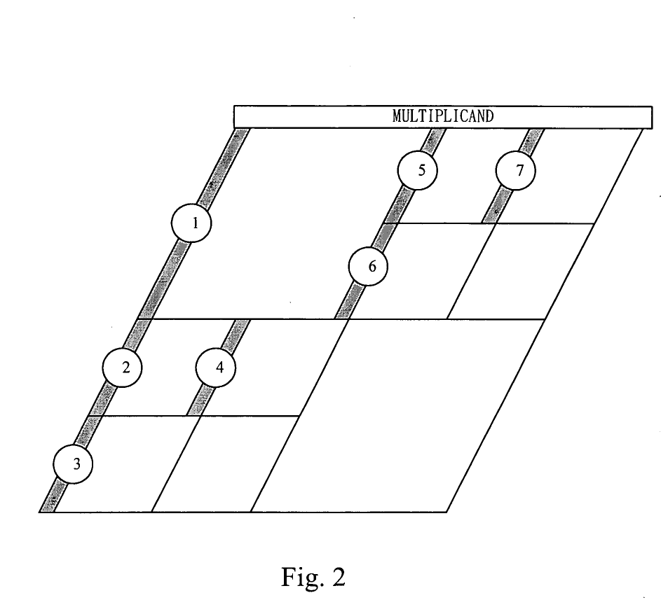

With reference to FIG. 2, which shows different zones of Booth decoders with circled numbers (1˜7) for three vector modes (e.g., 32×32, 16×16, and 8×8 for a 32×32 vector multiplier). If sign encoding is to be embedded, then Booth decoders in the numbered zones have to be modified. This embodiment now shows how it is possible to modify Booth decoders for vectored sign encoding with minimal hardware overhead. For brevity, this embodiment only provides descriptions of zone 1 and 5, and leaves the rest summarized in Table I.

Zone 1: In 32×32 mode, the appended bits for all partial products should be {p, n, n} or {1, p}, where n is the MSB of the multiplicand and p=˜n, in signed mode; or dependent on the Booth encoding result for unsigned mode. In either case, the value of n is known and the ‘1’ can be externally forced. Hence, there is no need to revise the Booth decoder shown in FIG. 1. On the other hand, in 16×16 and 8×8 modes, there should be no sign encoding and all Booth decoders in this zone need to be cleared to zero.

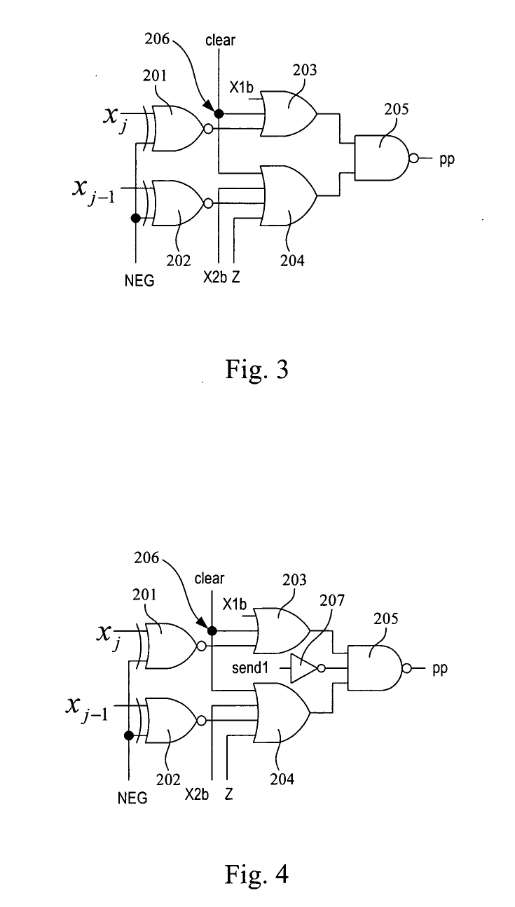

With reference to FIG. 3, this embodiment of the Booth decoder further implementations with a clear-to zero device 206. The clear-to-zero device 206 is to be added on the Booth decoder 200 as shown in FIG. 1. This implementation may be achieved by adding an additional OR gate on the Booth decoder 200. The clear-to zero device 206 is coupled to the first and the second OR gates 203,204 with its output being respectively coupled to the inputs of the OR gates 203,204. The clear-to-zero device 206 permits the Booth decoder to be cleared to zero.

Zone 5: In 32×32 mode, the Booth decoder 200 may be used. In 16×16 mode, on the other hand, the Booth decoders should provide {p, n, n} or {1, p} as those in zone 1 for 32×32 mode. Since vector mode can be changing along the course of computation, it is not possible to resort to hardware wiring to provide the “1” as the scalar sign encoding does. Therefore, the Booth decoders in zone 5 must have the capability of delivering a “1” during 16×16 mode, and resume the scalar Booth functions in 32×32 mode. Finally, in 8×8 mode, all Booth decoders in this zone need to be cleared to zero. The last requirement has already been fulfilled by the clear-to-zero device 206.

With reference to FIG. 4, in order to provide the capability of delivering a one, this embodiment further comprises a send-one device. The send-one device is implemented with an inverter 207. The output of the inverter 207 is one of the inputs of the NAND gate 205. The inverter 207 is coupled to the NAND gate 205.

The Booth decoding apparatus in accordance with the present invention has several advantages. The critical paths are properly maintained by careful balancing. The result is that the logic depth of the Booth decoder in accordance with the present invention is exactly the same as that of the original Booth decoder. Compared to the peripheral multiplexing method where additional multiplexing delay is inevitable, the present invention has a clear advantage of minimizing the delay overhead. Moreover, the present invention does not have to hold the data for multiplexing. Compared to the peripheral multiplexing method where many extra hardware components are required to support various vector modes under all Booth encodings (±1, ±2, 0), tremendous area saving is achieved.

TABLE I

| | 32x32 | 16x16 | 8x8 |
|---|---|---|---|
| Zone 1 | OBD | Clear-to-zero | Clear-to-zero |
| Zone 2 | OBD | OBD | Clear-to-zero |
| Zone 3 | OBD | OBD | OBD |
| Zone 4 | OBD | OBD | Send-one |
| Zone 5 | OBD | Send-one | Clear-to-zero |
| Zone 6 | OBD | Send-one | Send-one |
| Zone 7 | OBD | OBD | Send-one |

LEGEND:
OBD—Original Booth Decoder

Meanwhile, for a given partial product, if the result of Booth decoding is negative (−1 or −2), then the multiplicand must be two's complemented, i.e., inverting the bits and adding one to the LSB. Instead of employing a partial product for the increment, the extra one can be appended to the next partial product. This is known as the “hot one” technique as previously described.

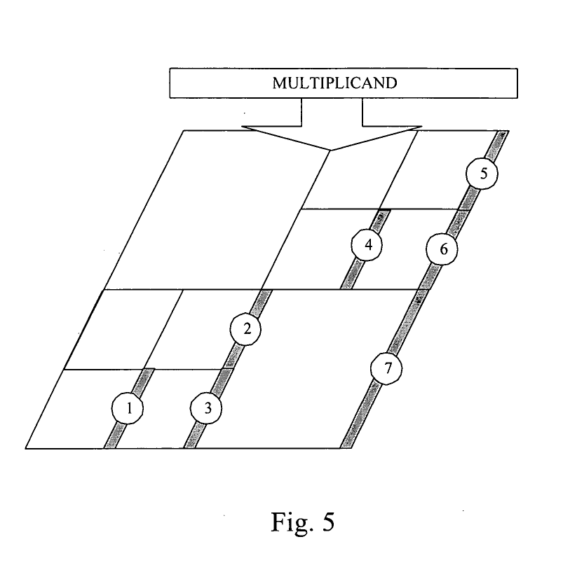

With reference to FIG. 5, to generate the hot ones using the original Booth decoders, this embodiment resorts to the zone partitions, where a total of seven zones of Booth decoders are involved in the generation of “hot ones”.

Taking zone 2 as the example, in 32×32 mode, the Booth decoders in this zone should remain as the booth decoder 200 shown in FIG. 1. In 16×16 and 8×8 modes, the necessity of hot ones depends on the Booth encoding result. If the result is negative, the Booth decoder should produce a ‘1’. Otherwise, a ‘0’ should be generated. Similar reasoning can be made on the rest of zones to reach the summary of Table II, where “Send-one/Clear-to-zero” is used to designate the condition of generating a hot one or simply a ‘0’ and is implemented with the clear-to-zero device 206 and the send-one device.

TABLE II

| | 32x32 | 16x16 | 8x8 |
|---|---|---|---|
| Zone 1 | OBD | OBD | Send-one/ |
| | | | Clear-to-zero |
| Zone 2 | OBD | Send-one/Clear-to- | Send-one/ |
| | | zero | Clear-to-zero |
| Zone 3 | OBD | Send-one/ | OBD |
| | | Clear-to-zero | |
| Zone 4 | OBD | OBD | Send-one/ |
| | | | Clear-to-zero |
| Zone 5 | Send-one/ | Send-one/ | Send-one/ |
| | Clear-to-zero | Clear-to-zero | Clear-to-zero |
| Zone 6 | Send-one/ | Send-one/ | OBD |
| | Clear-to-zero | Clear-to-zero | |
| Zone 7 | Send-one/Clear-to- | OBD | OBD |
| | zero | | |

### Legend: OBD—Original Booth Decoder

The result in Table II shows that to support hot ones for the two's complement of the multiplicand, it is only necessary to augment the original scalar Booth decoder with two functions: generating a ‘1’ or clearing to ‘0’. The present invention provides both functions with the implementations of the clear-to-zero device 206 and the send-one device. In other words, the embedding of “hot ones” is realized with virtually zero overhead.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A decoding apparatus for Booth vector multiplication, and the decoding apparatus comprising
a NAND gate;
a first OR gate having an output coupled to the NAND gate;
a second OR gate having an output coupled to the NAND gate;
a first exclusive NOR gate having an output coupled to the first OR gate;
a second exclusive NOR gate having an output coupled to the second OR gate;
a clear-to-zero device coupled to the first OR gate and the second OR gate to permit the decoding apparatus delivering a zero; and
a send-one device having an output coupled to the NAND gate to permit the decoding apparatus delivering a one.

2. The decoding apparatus as claimed in claim 1, wherein each of the first OR gate and the second OR gate has an input, and the clear-to-zero device has an output coupled to both the inputs of the first OR gate and the second OR gate.

3. The decoding apparatus as claimed in claim 1, wherein the send-one device is an inverter, and the inverter has an output coupled to the NAND gate.

4. The decoding apparatus as claimed in claim 1, wherein the decoding apparatus is used for signed vector Booth multiplication.

5. The decoding apparatus as claimed in claim 1, wherein the decoding apparatus is used for unsigned vector Booth multiplication.
